(19) United States
(12) Patent Application Publication
(10) Pub. No.: US 2007/0187785 A1
(43) Pub. Date: Aug. 16, 2007

(54) MAGNETIC MEMORY CELL AND MANUFACTURING METHOD THEREOF

(76) Inventors: Chien-Chung Hung, Taipei City (TW); Jian-Gang Zhu, Pittsburgh, PA (US); Ming-Jer Kao, Tainan City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/307,658

(22) Filed: Feb. 16, 2006

(51) Int. Cl. H01L 43/00

(52) U.S. Cl. 257/421

(57) ABSTRACT

A magnetic memory cell and a manufacturing method for the magnetic memory cell are provided. In the magnetic memory cell, a pinned layer of a magnetic bottom electrode can be formed with sizes different from the free layer. The wider magnetic bottom electrode produces a preferable uniform bias field that will create a normal magnetization vector distribution in the end domain of the free layer, and thus achieving a preferred switching property. The above process can also be achieved through self-alignment. In addition, by adjusting the bias field of the bottom electrode, uniform field distribution over entire free layer can be significantly improved, and thus the magnetic memory cell will have a very low writing toggle current.

### BACKGROUND OF THE INVENTION

1. Field of Invention

The present invention relates to a magnetic memory cell and the manufacturing method thereof, more particularly to a magnetic memory cell having a wide magnetic bottom electrode for producing a preferred uniform stray field and the manufacturing method thereof.

2. Description of Related Art

Magnetic random access memory (MRAM) has the advantages of non-volatility, high intensity, high read and write speed, radiation resistance, and so on. When writing data, generally two current lines, i.e., bit line and write word line are used, wherein a memory cell selected by the intersection of induction magnetic fields of the bit line and write word line has its resistance changed by changing the magnetization direction of the magnetic material of the memory layer. When reading the memory data, the current flows into the selected magnetic memory cell, and the resistance of the cell is read to determine the digital value of the memory data.

The magnetic memory cell is a stack structure of multiple magnetic metallic material layers, which is formed by a stack of a soft magnetic layer, a tunneling barrier layer, a hard magnetic layer, and a nonmagnetic conductor layer. Through the parallel or anti-parallel magnetic direction of the two layers of magnetic materials, “0” or “1” state of the memory is determined.

Because of the difficulty of controlling the manufacturing process of a magnetic memory cell, each bit within the MRAM memory product may be of a different shape. However, the control of the end domain is very important for a magnetic memory unit. The uneven and different size of the magnetic writing field of each bit will lead to an unsatisfactory write selectivity of the current magnetic memory. Accordingly, mass production of magnetic memory is very difficult.

In U.S. Pat. No. 6,545,906, a toggle mode different from the conventional cross selection is employed to significantly enhance the write selectivity of magnetic memory, so as to get closer to the mass production of magnetic memory. However, the special writing mode of the toggle mode requires a large magnetic writing field, and thus the write current of this product is also too large to cooperate with peripheral systems.

Furthermore, in the conventional technique, U.S. Pat. No. 6,633,498 proposes adding an additional magnetic field H_{BIAS} to the resultant vector direction of the magnetic fields produced by the two write lines (the write word line magnetic field H_{W} and bit line magnetic field H_{D}) to adjust the writing curve of the toggle mode, thus achieving a power saving effect, i.e., switching from the original domain 120 in FIG. 1 to the domain 220 in FIG. 2. Generally, to achieve an effect of the added magnetic field, a permanent magnet or an electrical magnet is added when packaging a memory. However, the simplest way is to make use of the thickness difference of the SAF pinned layer to produce a stray field. The stray field becomes a bias field imposed on the free layers. The larger the thickness difference, the stronger the resulting bias field. However, this process has its limitations, that is, when the bias field achieves a certain level of strength, the stability of the free layer becomes rather poor.

When adding a strong bias field H_{BIAS}, the magnetization vectors are distributed irregularly at the end domain of the memory cell, such as a magnetic memory cell 300 shown in FIG. 3 having a nonmagnetic conductor layer (e.g., Ru, Ta, Cu, or other coupling spacer) 320 between the first free layer (Free 1) 310 and the second free layer (Free 2) 330 made of magnetic material layer. Additionally, a nonmagnetic conductor layer (Ru, Ta, Cu, or other coupling spacers) 360 is disposed between the top pinned (TP) layer 350 and the bottom pinned (BP) layer 370 formed by magnetic material layers. Also, a tunnel barrier layer 340 is disposed between the second free layer (Free 2) 330 and the TP layer 350, and the tunnel barrier layer 340 can be AlOx, MgO, or another high dielectric layer. As mentioned above, when the bias field H_{BIAS} is too strong, the magnetization vectors are distributed irregularly at the end domain of the first free layer 310 and the second free layer 330 as shown in the figure, especially the area closer to the second free layer 330, thus increasing the difficulty of switching the magnetic elements and raising the writing error ratio.

The conventional process for manufacturing the magnetic memory cell of the magnetic random access memory (MRAM) is to etch and cut off all the magnetic films in one go. As for the conventional magnetic tunneling junction (MTJ) with a single free layer shown in FIG. 4, the MTJ includes a first magnetic sector formed of a top electrode 410 and a free magnetic layer (FM) 420; a second magnetic sector 440 formed of a top pinned layer 442, a magnetic coupling spacer layer 444, and a bottom pinned layer 446; and a tunneling barrier layer 430 disposed between the first magnetic sector and the second magnetic sector, wherein the tunneling barrier layer 430 may be made of Al₂O₃ or MgO. The magnetic coupling spacer layer 444 is a Ruthenium (Ru) layer as shown in the figure. The MTJ is constructed on the BE definition layer. The BE definition layer includes an anti-ferromagnetic layer (PtMn) 450 and a bottom electrode 460. The MTJ of the MRAM employs the way of etching to cut off all the magnetic films in one go, that is, the top electrode 410, the free magnetic layer 420, the tunneling barrier layer 430, the top pinned layer 442, the magnetic coupling spacer layer 444, and the bottom pinned layer 446 are formed by etching directly.

As for the MTJ of the conventional sandwiched synthetic anti-ferromagnetic (SAF) free layer shown in FIG. 5, the MTJ includes a top electrode 510, a first SAF free layer 520, a tunneling barrier layer 530, and a second SAF pinned layer 540. The first SAF free layer 520 includes a first free magnetic (FM) layer 522, a magnetic coupling spacer layer (Ru) 524, and a second FM layer 526. The second SAF pinned layer 540 is formed of a top pinned layer 542, a magnetic coupling spacer layer (Ru) 544, and a bottom pinned layer 546. The MTJ is constructed on the BE definition layer, wherein the BE definition layer includes an anti-ferromagnetic layer (PtMn) 550 and a bottom electrode 560. The MTJ of the MRAM employs the way of etching to cut off all the magnetic films in one go, that is, the top electrode 510, the first SAF free layer 520, the tunneling barrier layer 530, and the second SAF pinned layer 540 are formed by etching directly.

As seen from FIGS. 4 and 5, the magnetic elements manufactured by the processes of the magnetic memory cell of the MRAM having two different structures suffer a strong magnetic field at the end domain of the free layer, such that the magnetization vectors in the end domain for the free layer are distributed irregularly, as shown in FIG. 3, thus increasing the difficulty in switching the magnetic elements.

### SUMMARY OF THE INVENTION

The invention provides a magnetic memory cell including an SAF bottom electrode pinned layer having a size different from the free layer, thus forming the magnetic bottom electrodes with various shapes through the mask alignment. The wide magnetic bottom electrode produces a preferable uniform bias field, creating a normal magnetization vector distribution in the end domain of the free layer, and thus a preferred switching property.

In another embodiment of the present invention, a wide magnetic bottom electrode having a shape similar to the free layer can be achieved through self-alignment. In this way, the deviation during aligning different mask layers can be eliminated, thus achieving preferred uniformity in manufacture.

Through adjusting the bias field of the bottom electrode by the magnetic memory cell, the uniform field distribution over entire free layer can be significantly improved, and the magnetic memory cell has a very low writing magnetic field.

To achieve the above objects, a magnetic memory cell is provided, which includes a free magnetic sector, a tunneling barrier layer, an SAF bottom electrode (SAF-BE) pinned layer, and a bottom electrode (BE) definition layer. The tunneling barrier layer is sandwiched between the free magnetic sector and the SAF-BE pinned layer. The BE definition layer is located below the SAF-BE pinned layer. The width of the free magnetic sector is smaller than that of the SAF-BE layer.

The free magnetic sector of the above magnetic memory cell includes a top electrode and a free layer or an SAF free layer.

In the above magnetic memory cell, within a portion of the free magnetic sector whose width is smaller than the SAF-BE layer, a spacer is formed on the side edge of a magnetic tunneling junction (MTJ).

The SAF-BE pinned layer of the above magnetic memory cell is rectangular, round, or oval shaped.

To achieve the above objects, a process for manufacturing the magnetic memory cell is provided. First, a front-end-of-line process for a magnetic structure is carried out to form a stack of a bottom electrode material layer, an SAF-BE pinned material layer, a tunneling barrier layer, and a free magnetic sector. The tunneling barrier material layer is sandwiched between the free magnetic sector material layer and the SAF-BE pinned material layer. The bottom electrode material layer is located below the SAF-BE pinned material layer. Then, the free magnetic sector material layer is etched with the tunneling barrier material layer as a first etching stop layer, so as to form a free magnetic sector. And then a mask process is carried out with the bottom electrode material layer as a second etching stop layer, so as to define a tunneling barrier layer and an SAF-BE pinned layer capable of producing an bias field. The width of the SAF-BE pinned layer is larger than that of the free magnetic sector. After that, the bottom electrode material layer is patterned, so as to form the bottom electrode (BE) definition and the bit line (BL).

To achieve the above objects, a process for manufacturing the magnetic memory cell is provided. First, the front-end-of-line process for a magnetic structure is carried out to form a stack of a bottom electrode material layer, an SAF-BE pinned material layer, a tunneling barrier material layer, and a free magnetic sector. The tunneling barrier material layer is sandwiched between the free magnetic sector material layer and the SAF-BE pinned material layer. The bottom electrode material layer is located below the SAF-BE pinned material layer. Then, the free magnetic sector material layer is etched with the tunneling barrier material layer as a first etching stop layer to from a free magnetic sector. And a film layer is formed above the free magnetic sector, and a spacer is formed on the side edge of the free magnetic sector through etch back. Then, an SAF-BE pinned layer capable of producing bias field is defined by self-align etching of the spacer with the bottom electrode material layer as a second etching stop layer. The width of the SAF-BE pinned layer larger than the free magnetic sector is the thickness of the spacer. The bottom electrode material layer is patterned so as to form a bottom electrode (BE) definition and a bit line (BL)

In order to the make the aforementioned and other objects, features and advantages of the present invention comprehensible, a preferred embodiment accompanied with figures is described in detail below.

### BRIEF DESCRIPTION OF THE DRAWINGS

FIG. 1 is a schematic view of a conventional toggle writing curve;

FIG. 2 is a schematic view of a toggle writing curve after being added with a bias field H_{BIAS};

FIG. 3 depicts an irregular distribution of the magnetization vectors in the end domain of the memory cell when applying a strong bias field (H_{BIAS});

FIG. 4 is a schematic view of a conventional magnetic tunneling junction (MTJ) structure with a single free layer;

FIG. 5 is a schematic view of a conventional MTJ structure with a sandwiched SAF free layer;

FIG. 6 is a schematic structural view of an MTJ structure with a single free layer according to the first embodiment of the present invention;

FIG. 7 is a schematic view of an MTJ structure with a sandwiched SAF free layer according to the first embodiment of the present invention;

FIG. 8 is a flow chart for manufacturing an MTJ according to the first embodiment of the present invention;

FIG. 9 is a schematic front view of the mask layout according to the first embodiment of the present invention;

FIG. 10 is a schematic structural view of an MTJ structure with a signal free layer according to the second embodiment of the present invention;

FIG. 11 is a schematic structural view of an MTJ structure with a sandwiched SAF free layer according to the second embodiment of the present invention;

FIG. 12 is a flow chart for manufacturing an MTJ according to the second embodiment of the present invention;

FIG. 13 is a schematic front view of the mask layout according to the second embodiment of the present invention;

FIG. 14A is a diagram illustrating the properties of the general toggle magnetic memory cell; and

FIG. 14B is a diagram explaining the application of the magnetic memory cell according the embodiments of the present invention.

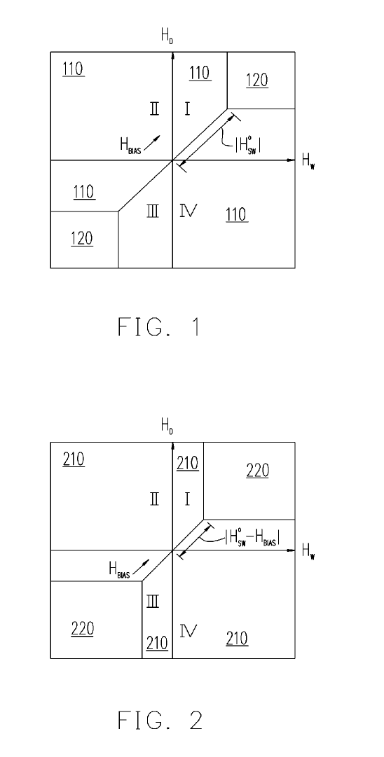

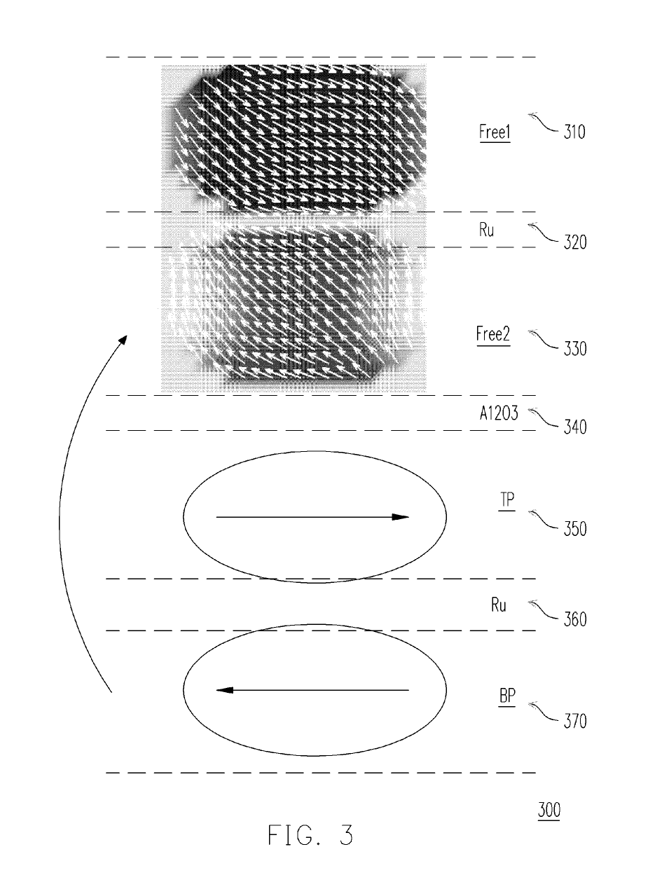

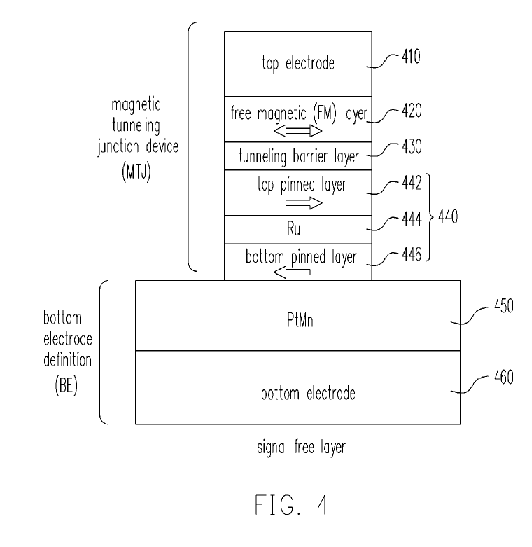

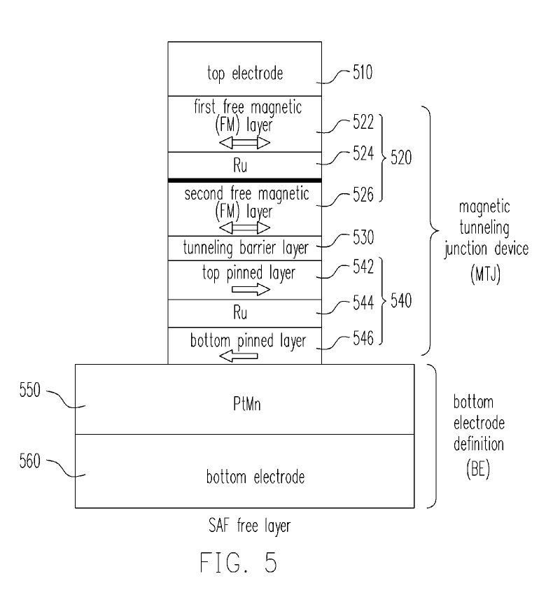

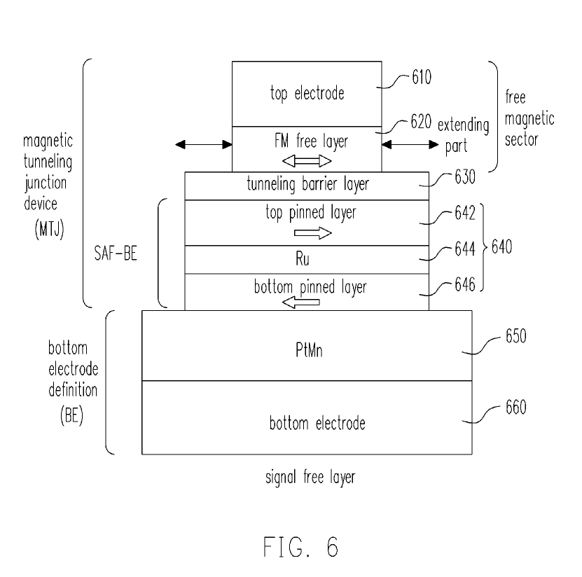

### DESCRIPTION OF EMBODIMENTS

The present invention provides a magnetic memory cell which includes an SAF-BE pinned layer having a size different from the free layer, thus forming the bottom electrodes with various shapes (such as rectangle) through the mask alignment. The wider magnetic bottom electrode produces a preferable uniform bias field that will provide a normal magnetization vector distribution in the end domain of the free layer, and thus a preferred switching property can be achieved.

In another embodiment of the present invention, a wider magnetic bottom electrode having a shape similar to the free layer can be achieved through self-alignment. In this way, the deviation during aligning different mask layers can be eliminated, thus achieving preferred manufacturing uniformity. With the magnetic memory cell provided in the present invention, by adjusting the bias field of the magnetic bottom electrode, uniform field distribution over the entire free layer can be significantly improved, and thus the magnetic memory cell has a very low writing toggle current.

The magnetic memory cell, made up of multiple magnetic films, generally includes: a bottom electrode, a buffer layer (such as NiFe or NiFeCr), an anti-ferromagnetic layer (such as PtMn or MnIr), a magnetic pinned layer or SAF pinned layer (such as CoFe/Ru/CoFe), a tunneling barrier layer (such as, AlO_{X} or MgO), an FM free layer (such as, NiFe/CoFe, CoFeB, or SAF free layer), and a top electrode, etc.

### First Embodiment

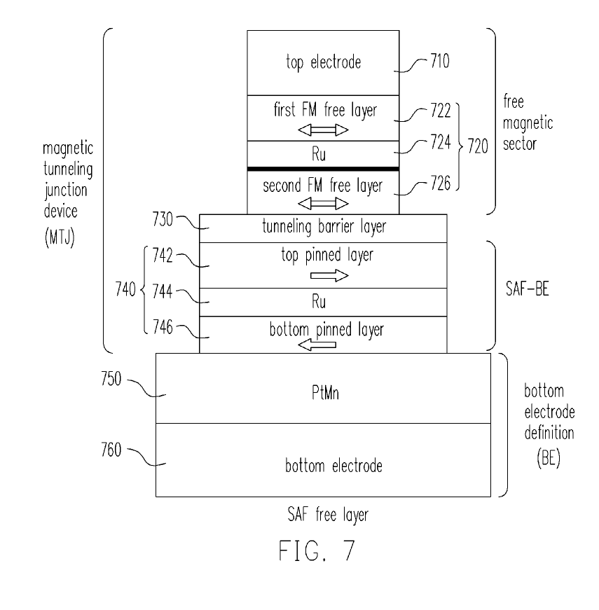

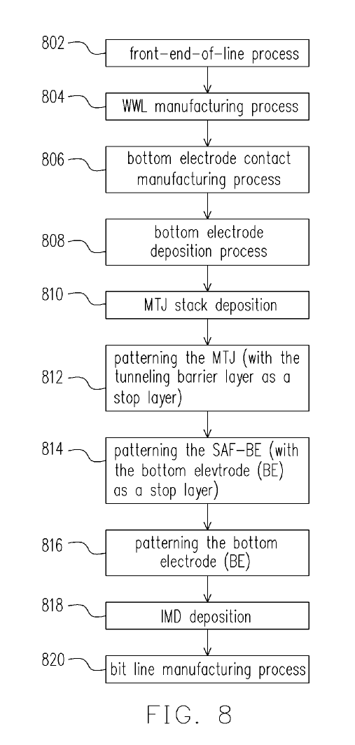

The magnetic memory in this embodiment can be a single free layer as shown in FIG. 6, or a sandwiched SAF free layer as shown in FIG. 7, which will be illustrated in detail below. The data state is determined by the magnetic memories in such a way that the parallel or anti-parallel arrangement of the two magnetic layers on both sides of the tunneling barrier layer (Al₂O₃ or MgO) are utilized to determine the data stored in the memory cell.

The magnetic tunneling junction (MTJ) with a single free layer as shown in FIG. 6 includes a free magnetic sector, a tunneling barrier layer, an SAF pinned layer, and a bottom electrode. The free magnetic sector includes a top electrode 610, a ferro-magnetic (FM below) free layer 620, wherein the FM free layer 620 is made of, for example, NiFe/CoFe, CoFeB, or an SAF free layer, etc. The tunneling barrier layer 630 can be made of Al₂O₃ or MgO for insulating the wider SAF-BE pinned layer 640 capable of producing a bias field. The SAF-BE pinned layer 640 includes a magnetic pinned layer or an SAF pinned layer (such as CoFe/Ru/CoFe, etc.), such as a top pinned layer 642 shown in the drawing, a magnetic coupling spacer layer 644, and a bottom pinned layer 646. Wherein, the magnetic coupling spacer layer 644 can be Ruthenium (Ru), copper, Ta, or other materials. And a bottom electrode (BE) definition is provided at the bottom part, which includes a bottom electrode 660, a buffer layer (such as NiFe or NiFeCr) and an anti-ferromagnetic layer (such as PtMn or MnIr) 650.

As for the magnetic memory cell provided in the present invention, the main structural feature is that the width of the free magnetic sector is smaller than that of the SAF-BE pinned layer 640, and an extension portion is between them as illustrated. Accordingly, bottom electrodes having various shapes (such as rectangle) can be formed through the mask alignment. The wider magnetic bottom electrode produces a preferable uniform bias field, providing a normal magnetization vector distribution in the end domain of the free layer of the MTJ, and thus a preferred switching property can be obtained. By adjusting the thicknesses of the top pinned layer 642 and the bottom pinned layer 646, the switching field for the free layer of the MTJ can be reduced. The SAF-BE pinned layer 640 can be rectangular, round, or oval shaped. In addition, the SAF-BE pinned layer 640 also can be shaped through self-alignment of the free layer of the free magnetic sector, which will be illustrated in different steps below.

The MTJ with sandwiched SAF free layer shown in FIG. 7 includes a free magnetic sector, a tunneling barrier layer, an SAF pinned layer, and a bottom electrode. The free magnetic sector includes a top electrode 710, a first SAF free layer 720. A tunneling barrier layer 730 and an SAF-BE pinned layer 740 are provided below. The first SAF free layer 720 includes a first FM free layer 722, a magnetic coupling spacer layer (Ru) 724, and a second FM free layer 726. The tunneling barrier layer 730 is made of Al₂O₃ or MgO for insulating the wider SAF-BE pinned layer 740 capable of producing a bias field. The SAF-BE pinned layer 740 includes a magnetic pinned layer or an SAF pinned layer (such as a CoFe/Ru/CoFe), etc, such as a top pinned layer 742, a magnetic coupling spacer layer 744, and a bottom pinned layer 746 shown in the drawing. The magnetic coupling spacer layer 744 can be made of ruthenium (Ru), copper, or Ta, or other materials. A bottom electrode (BE) definition is provided at the bottom part, which includes a bottom electrode 760, a buffer layer (such as NiFe or NiFeCr), and an anti-ferromagnetic layer (such as PtMn or MnIr) 750.

As for the magnetic memory cell provided in the present invention, the main structural feature is that the width of the free magnetic sector is smaller than that of the SAF-BE pinned layer 740. Accordingly, bottom electrodes having various shapes (such as rectangle) can be achieved through the mask alignment. The wider magnetic bottom electrode produces a preferable uniform bias field, providing a normal magnetization vector distribution in the end domain of the free layer of the MTJ, and thus a preferred switching property can be achieved. By adjusting the thicknesses of the top pinned layer 742 and the bottom pinned layer 746, the switching field for the free layer of the MTJ can be reduced. The SAF-BE pinned layer 740 can be rectangle, round, or oval shaped. In addition, the SAF-BE pinned layer 740 also can be shaped through the self-alignment of the free layer of the free magnetic sector, which will be illustrated in different steps below.

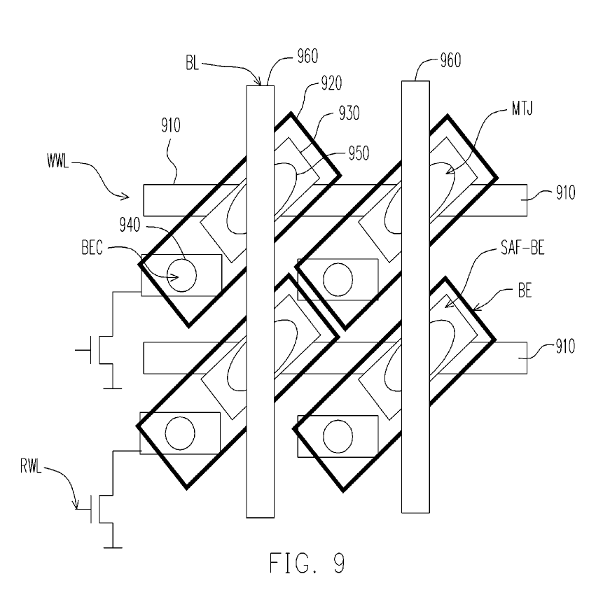

The manufacturing process for the MTJ with a single free layer according to an embodiment of the present invention is shown in FIG. 8. The front-end-of-line process for the magnetic structure is first completed which includes step 802 for manufacturing a front end complementary metal-oxide semiconductor CMOS), step 804 for forming a write word line (WWL), step 806 for forming a bottom electrode contact (BEC), step 808 for depositing the bottom electrode, and step 810 for depositing an MTJ stack.

Then, step 812 is carried out, wherein as the magnetic memory is etched, the tunneling barrier layer acts as an etching stop layer. After that, in step 814, a mask process is carried out to define a wider SAF-BE pinned layer capable of producing a bias field with the bottom electrode (BE) definition as an etching stop layer. Then, in step 816, the bottom electrode (BE) definition is patterned, and the following bit line (BL) manufacturing process is completed, which includes the process for depositing an inter-metal dielectric (IMD) layer in step 818 and the process for forming a bit line (BL) in step 820.

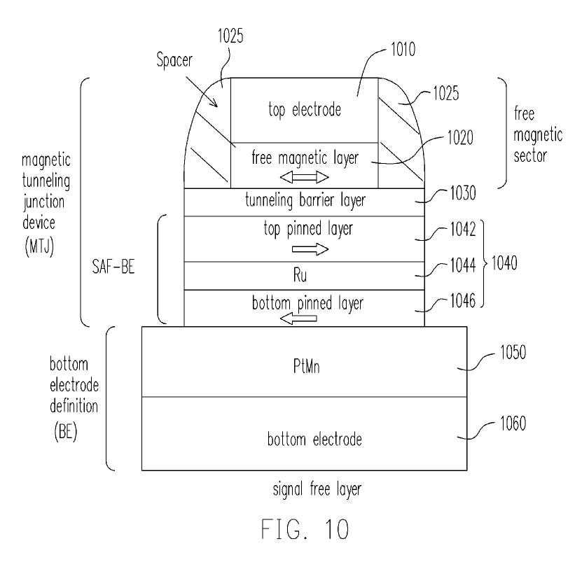

A schematic top view of a mask layout according to an embodiment of the present invention is shown in FIG. 9, wherein an easy axis of the magnetic memory forms an angle of 45 degrees with the WWL 910, the BL 960, and that is the so-called toggle write layout. In this schematic view of the layout, a wider SAF-BE pinned layer 930 is provided below the free magnetic sector 950, and below the SAF-BE pinned layer 930 is the BE definition 920 and the bottom electrode contact (BEC) 940. In this way, a very low writing current can be achieved.

### Second Embodiment

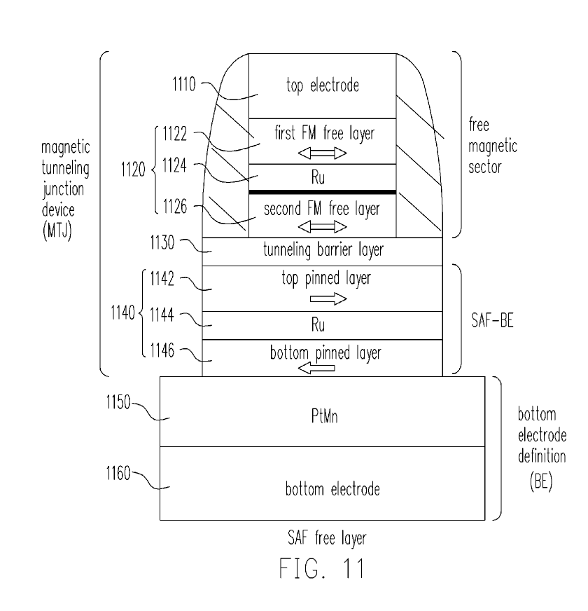

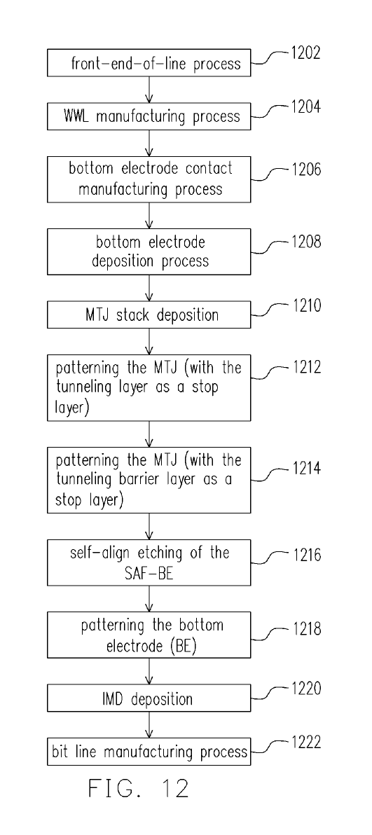

The magnetic memory in this embodiment can be a single free layer as shown in FIG. 10, or a sandwiched SAF free layer as shown in FIG. 11, which will be illustrated below in detail.

The MTJ with a single free layer in this embodiment as shown in FIG. 10 includes a free magnetic sector, a tunneling barrier layer, an SAF pinned layer, and a bottom electrode. The free magnetic sector includes a top electrode 1010, and an FM free layer 1020. The FM free layer 1020 is made of, for example, NiFe/CoFe, CoFeB, or the SAF free layer, etc. The tunneling barrier layer 1030 is made of Al₂O₃ or MgO for insulating the wider SAF-BE pinned layer 1040 capable of producing a bias field. The SAF-BE pinned layer 1040 includes a magnetic pinned layer or an SAF pinned layer (such as CoFe/Ru/CoFe), such as a top pinned layer 1042, a magnetic coupling spacer layer 1044, and a bottom pinned layer 1046 shown in the drawing. A bottom electrode (BE) definition is provided at the bottom part, which includes a bottom electrode 1060, a buffer layer (such as NiFe or NiFeCr), and an anti-ferromagnetic layer (such as PtMn or MnIr) 1050.

As for the magnetic memory cell according to the present invention, the main structural feature is that the width of the free magnetic sector is smaller than that of the SAF-BE pinned layer 1040, thus a spacer is further formed at the side edge of the top electrode 1010 and the free magnetic layer 1020 through the process of self-alignment with the tunneling barrier layer 1030 as the etching stop layer.

The sandwiched SAF free layer of the MTJ in this embodiment is shown in FIG. 11, which includes a free magnetic sector, a tunneling barrier layer, an SAF pinned layer, and a bottom electrode. The free magnetic sector includes a top electrode 1110 and a first SAF free layer 1120. Below the free magnetic sector is a tunneling barrier layer 1130 and an SAF-BE pinned layer 1140; wherein the tunneling barrier layer 1130 is made of Al₂O₃ or MgO for insulating the wider SAF-BE pinned layer 1140 capable of producing a bias field. The SAF-BE pinned layer 1140 includes a magnetic pinned layer or an SAF pinned layer (such as CoFe/Ru/CoFe etc.), such as a top pinned layer 1142, a magnetic coupling spacer layer 1144, and a bottom pinned layer 1146 shown in the drawing. The magnetic coupling spacer layer 1144 can be made of ruthenium (Ru), Cu, or Ta, or other materials. A bottom electrode (BE) definition is provided at the bottom part, which includes a bottom electrode 1160, a buffer layer (such as NiFe or NiFeCr), or an anti-ferromagnetic layer (such as PtMn or MnIr) 1150.

As for the magnetic memory cell provided in the present invention, the main structural feature is that the width of the free magnetic sector is smaller than that of the SAF-BE pinned layer 1140, thus a spacer is further formed at the side edges of the top electrode 1110 and the first SAF free layer 1120 through self-alignment with the tunneling barrier layer 1130 acting as the etching stop layer.

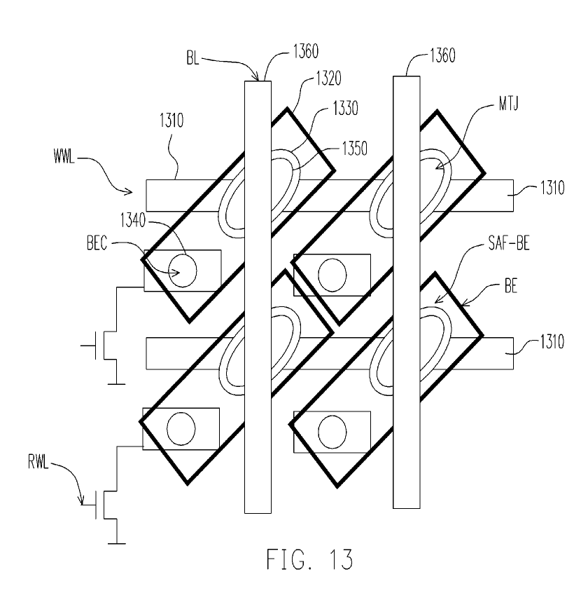

The manufacturing process for the MTJ according to the second embodiment of the present invention is shown in FIG. 12. The manufacturing process shown in FIG. 12 is employed in this second embodiment to avoid the deviation during aligning different mask layers. First, the front-end-of-line process for the magnetic structure is completed, which includes step 1202 for manufacturing a front end CMOS, step 1204 for forming a WWL, step 1206 for forming a BEC, step 1208 for depositing a BE, and step 1210 for depositing an MTJ stack.

When the magnetic memory is etched, such as in step 1212, first the tunneling barrier layer acts as an etching stop layer. Then, as in the process for forming a spacer in step 1214, a thin film is coated, and then etch back is carried out, thus the width of extended free layer of the spacer is controlled by the thickness of this layer. After that, as in step 1216, a wider SAF-BE capable of producing a bias field is defined with a shape similar to the free layer. Then, as in step 1218, the BE is patterned to a BE definition. Finally, the manufacturing process for the BL is performed, which includes the manufacturing processes of depositing the IMD layer in step 1220 and forming the BL in step 1222.

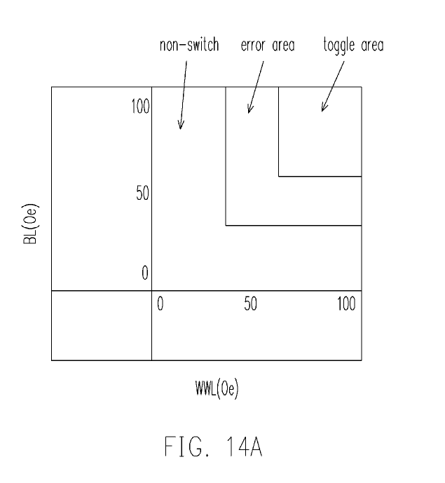

The top view of the mask layout according to the second embodiment is shown in FIG. 13, wherein the easy axis of the magnetic memory forms an angle of 45 degrees with the WWL 1310, the BL 1360, and that is the so-called toggle write layout. In the schematic view of layout, below the free magnetic sector, a wider SAF-BE pinned layer 1330 is formed; and below the SAF-BE pinned layer 1330 is a BE definition 1320 and a BEC 1340, thus a very low write current can be achieved.

As for the magnetic memory cell provided in the present invention, a magnetic BE pinned layer having a size different from the free layer is included, and bottom electrodes having various shapes (such as rectangle) can be formed through the mask alignment. The wider magnetic bottom electrode produces a preferable uniform bias field, providing a normal magnetization vector distribution in the end domain of the free layer, and thus a preferred switching property can be obtained. In another embodiment, a wider magnetic bottom electrode having the shape similar to the free layer can be achieved through self-alignment. In this way, the deviation during alignment of different mask layers can be eliminated; thereby achieving a preferred manufacturing uniformity. With the magnetic memory cell provided in the present invention, by adjusting the bias field of the magnetic bottom electrode, the field distribution over the entire free layer can be significantly improved, and the magnetic memory cell has a very low writing toggle current. The present invention is not only suitable for the toggle embodiment in FIGS. 6 to 13; when the writing mechanism of the free layer for the memory cell is the general cross selection mode, the wider magnetic bottom electrode resulted from the present invention also can be used, such that the magnetization is regularly distributed at the free layer, thus achieving a preferred switching property.

With the minimization of the elements, the impact from the bias field on the end domain of the magnetic memory cell is increased. The field distribution over the entire free layer can be significantly improved, thus the magnetic memory can be continuously minimized.

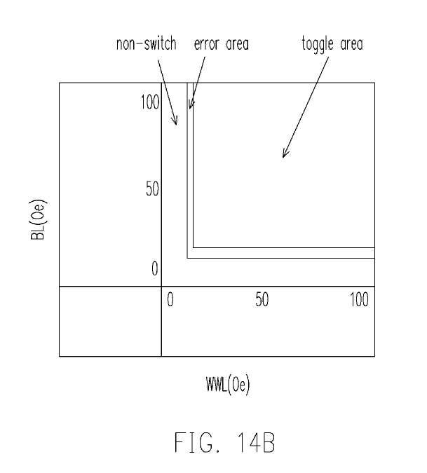

Based upon simulation, FIG. 14A is a diagram illustrating the property of a common toggle magnetic memory cell, wherein the width of the free magnetic sector is the same as the SAF-BE pinned layer with a weaker bias field. FIG. 14B shows an application of the magnetic memory cell according to the embodiment of the present invention, wherein the width of the SAF-BE pinned layer is larger than the free magnetic sector with a relatively strong bias field. A relatively strong bias field results when the difference between the thicknesses of the two magnetic layers of the SAF is relatively large. It can be seen by comparing FIG. 14A with FIG. 14B, the effective toggle operation area for the magnetic memory cell of the present invention is much larger compared with that of the common toggle magnetic memory cell. Besides, the present invention provides with narrower error area. This is because the wider magnetic bottom electrode formed according to the present invention is applied, such that the magnetic field is regularly distributed at the free layer, thus achieving a preferred switching property.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A magnetic memory cell, comprising:
a free magnetic sector;
a tunneling barrier layer;
a synthetic anti-ferromagnetic bottom electrode pinned layer (SAF-BE), wherein the tunneling barrier layer is sandwiched between the free magnetic sector and the SAF-BE pinned layer; and
a bottom electrode (BE) layer, located below the SAF-BE pinned layer, wherein the width of the free magnetic sector is smaller than that of the SAF-BE pinned layer.

2. The magnetic memory cell as claimed in claim 1, wherein the free magnetic layer comprises a top electrode and a free layer.

3. The magnetic memory cell as claimed in claim 2, wherein the free layer is made of NiFe/CoFe or CoFeB.

4. The magnetic memory cell as claimed in claim 1, wherein the free magnetic sector comprises a top electrode and a sandwiched synthetic anti-ferromagnetic free magnetic layer (SAF free layer).

5. The magnetic memory cell as claimed in claim 4, wherein the SAF free layer comprises a first free magnetic layer, a magnetic coupling spacer layer, and a second free magnetic layer.

6. The magnetic memory cell as claimed in claim 1, wherein the tunneling barrier layer is made of AlOx or MgO.

7. The magnetic memory cell as claimed in claim 1, wherein the SAF-BE pinned layer comprises a top pinned layer, a magnetic coupling spacer layer, and a bottom pinned layer.

8. The magnetic memory cell as claimed in claim 1, wherein the bottom electrode (BE) comprises an anti-ferromagnetic layer and a bottom electrode.

9. The magnetic memory cell as claimed in claim 8, wherein the anti-ferromagnetic layer is made of PtMn or MnIr.

10. The magnetic memory cell as claimed in claim 8, wherein a buffer layer is further provided between the anti-ferromagnetic layer and the bottom electrode.

11. The magnetic memory cell as claimed in claim 10, wherein the buffer layer is made of NiFe or NiFeCr.

12. The magnetic memory cell as claimed in claim 1, wherein the width of the free magnetic sector is smaller than that of the SAF-BE pinned layer, thereby a spacer is formed at a side edge of the free magnetic sector.

13. The magnetic memory cell as claimed in claim 1, wherein the SAF-BE pinned layer is rectangular, round, or oval shaped.

14. A method for manufacturing a magnetic memory cell, comprising:
carrying out a front-end-of-line process for a magnetic structure, and forming a stack of a bottom electrode material layer, an SAF-BE pinned material layer, a tunneling barrier material layer, and a free magnetic sector, wherein the tunneling barrier layer is sandwiched between the free magnetic sector and the SAF-BE pinned material layer, and the bottom electrode material layer is located below the SAF-BE pinned material layer;
etching the free magnetic sector material with the tunneling barrier material layer as a first etching stop layer, so as to form the free magnetic sector;
carrying out a mask process with the bottom electrode material layer as a second etching stop layer, so as to define a tunneling barrier layer and an SAF-BE pinned layer capable of producing a bias field, wherein the width of the SAF-BE pinned layer is larger than that of the free magnetic sector;
patterning the bottom electrode material layer to form a bottom electrode (BE); and forming a bit line (BL).

15. The method for manufacturing the magnetic memory cell as claimed in claim 14, wherein the free magnetic sector comprises a top electrode and a free layer.

16. The magnetic memory cell as claimed in claim 14, wherein the free magnetic sector comprises a top electrode and a sandwiched SAF free layer.

17. The magnetic memory cell as claimed in claim 16, wherein the SAF free layer comprises a first free magnetic layer, a magnetic coupling spacer layer, and a second free magnetic layer.

18. The magnetic memory cell as claimed in claim 14, wherein the SAF-BE pinned layer comprises a top pinned layer, a magnetic coupling spacer layer, and a bottom pinned layer.

19. The magnetic memory cell as claimed in claim 14, wherein the SAF-BE pinned layer is rectangular, round, or oval shaped.

20. A method for manufacturing a magnetic memory cell, comprising:
carrying out a front-end-of-line process for a magnetic structure, and forming a stack of a bottom electrode material layer, an SAF-BE pinned material layer, a tunneling barrier material layer, and a free magnetic sector; wherein the tunneling barrier material layer is sandwiched between the free magnetic sector and the SAF-BE pinned material layer, and the bottom electrode material layer is located below the SAF-BE pinned material layer;
etching the free magnetic sector material with the tunneling insulation material layer as a first etching stop layer, so as to form the free magnetic sector;
forming a thin film layer on the free magnetic sector, wherein a spacer is formed at the side edge of the free magnetic sector through etch back;
defining a tunneling barrier layer and an SAF-BE pinned layer capable of producing a bias field with the bottom electrode material layer as a second etching stop layer and with the spacer as the mask, wherein the width of the SAF-BE pinned layer larger than the free magnetic sector is the width of the spacer;
patterning the bottom electrode material layer to form a bottom electrode (BE); and forming a bit line (BL).

21. The method for manufacturing the magnetic memory cell as claimed in claim 20, wherein the free magnetic sector comprises a top electrode and a free layer.

22. The method for manufacturing the magnetic memory cell as claimed in claim 20, wherein the free magnetic sector comprises a top electrode and a sandwiched SAF free layer.

23. The method for manufacturing the magnetic memory cell as claimed in claim 22, wherein the SAF free layer comprises a first free magnetic layer, a magnetic coupling spacer layer, and a second free magnetic layer.

24. The magnetic memory cell as claimed in claim 20, wherein the SAF-BE pinned layer comprises a top pinned layer, a magnetic coupling spacer layer, and a bottom pinned layer.

25. The magnetic memory cell as claimed in claim 20, wherein the SAF-BE pinned layer is rectangular, round, or oval shaped.
